(19) United States
(12) Patent Application Publication
(10) Pub. No.: US 2025/0125216 A1
(43) Pub. Date: Apr. 17, 2025

(54) DIE AND MANUFACTURING METHOD THEREOF AS WELL AS SEMICONDUCTOR PACKAGE WITH THE SAME

(71) Applicant: Orient Semiconductor Electronics, Limited, Kaohsiung City (TW)

(72) Inventors: YUEH-MING TUNG, Kaohsiung City (TW); CHIA-MING YANG, Kaohsiung City (TW); GUAN-LIN PAN, Kaohsiung City (TW); YING-CHIH LEE, Kaohsiung City (TW); PO-YEN YEN, Kaohsiung City (TW)

(21) Appl. No.: 18/906,435

(22) Filed: Oct. 4, 2024

(30) Foreign Application Priority Data
Oct. 11, 2023 (TW) 112138720

(51) Int. Cl. H01L 23/373; H01L 21/02; H01L 21/78; H01L 23/00; H01L 23/31

(52) U.S. Cl. CPC H01L 23/3736; H01L 21/02013; H01L 21/02016; H01L 21/02035; H01L 21/78; H01L 23/3128; H01L 24/16; H01L 2224/16225; H01L 2924/1015; H01L 2924/18161

(57) ABSTRACT

The present disclosure provides a die. The die of the present disclosure has a top surface, a plurality of side surfaces, a bottom surface, a circuit layer and a platform. The bottom surface is connected to the side surfaces. The circuit layer is formed on the bottom surface. The platform is disposed around the top surface and is parallel to the top surface and the bottom surface. The distance from the platform to the bottom surface is less than that from the top surface to the bottom surface. The platform is perpendicularly connected to the side surfaces. The present disclosure further provides a method of manufacturing the above die and a semiconductor package with the die.

### CROSS-REFERENCE TO RELATED APPLICATIONS

The present application is based on and claims priority to Taiwanese Application Number 112138720, filed Oct. 11, 2023, the disclosure of which is hereby incorporated by reference herein in its entirety.

### FIELD OF THE DISCLOSURE

This disclosure relates to a die and a manufacturing method thereof as well as a semiconductor package with the same, and more particularly relates to a die that may prevent separation from a molding layer and a manufacturing method thereof as well as a semiconductor package with the same.

### BACKGROUND OF THE DISCLOSURE

Referring to FIG. 1, a conventional semiconductor package made by flip chip technology includes a die 110 disposed on a substrate 120. A circuit layer 116 is provided on the front surface of the die 110 and is electrically connected to the substrate 120 by means of a plurality of metal bumps 130. A molding layer 140 is formed on the substrate 120 to cover a plurality of side surfaces of the die 110. The molding layer 140 is not formed on the back surface of the die 110.

A heat spreader (not shown) may be disposed on the top of the above-described semiconductor package to help dissipate heat from the die 110. However, since the molding layer 140 does not cover the top of the die 110, the difference in coefficient of thermal expansion between the die 110 and the molding layer 140 results in the side surfaces of the die 110 easily separating from the molding layer 140.

### SUMMARY

In view of the above, the present disclosure provides a die and a manufacturing method thereof as well as a semiconductor package with the same, in order to solve the above problems.

In one embodiment, the die of the present disclosure has a top surface, a plurality of side surfaces, a bottom surface, a circuit layer and a platform. The bottom surface is connected to the side surfaces. The circuit layer is formed on the bottom surface. The platform is disposed around the top surface and is parallel to the top surface and the bottom surface. The distance from the platform to the bottom surface is less than that from the top surface to the bottom surface. The platform is perpendicularly connected to the side surfaces.

In one embodiment, the semiconductor package of the present disclosure includes a substrate, the above die, a plurality of metal bumps and molding layer. The die is disposed on the substrate. The metal bumps are disposed between the substrate and the bottom surface of the die and are electrically connected to the circuit layer of the die. The molding layer is formed on the substrate to cover the side surfaces and the platform of the die, wherein the molding layer exposes the top surface of the die.

In one embodiment, the method of manufacturing a die according to the present disclosure comprises: providing a wafer having a front surface and a back surface opposing to the front surface, wherein a circuit layer is formed on the front surface; grinding the back surface of the wafer with a grinding bit to thin the wafer to a predetermined thickness; forming a plurality of grooves on the back surface of the wafer; and dicing the wafer from the front surface to the grooves with a dicing blade.

In the semiconductor package of the present disclosure, as the molding layer covers the platform, it hooks onto the die like a hook so that the die is not easily separated from the molding layer.

The foregoing, as well as additional objects, features and advantages of the disclosure will be more readily apparent from the following detailed description, which proceeds with reference to the accompanying drawings.

### BRIEF DESCRIPTION OF DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic diagram of a conventional semiconductor package.

FIG. 2 is a schematic diagram of the semiconductor package of the present disclosure.

FIGS. 3 to 8 illustrate the method of manufacturing the die of FIG. 2.

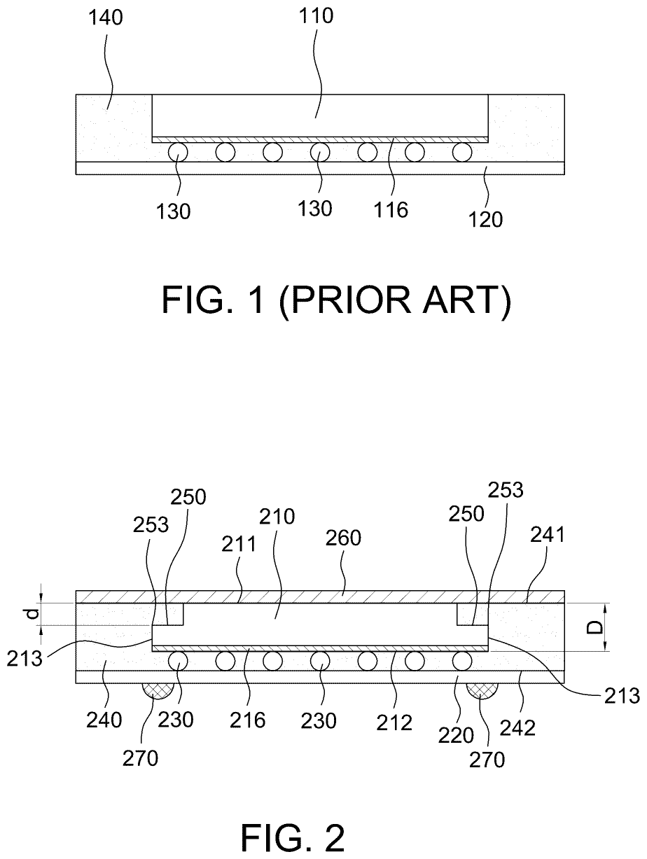

### DETAILED DESCRIPTION OF THE DISCLOSURE

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatial relative terms, such as “beneath.” “below,” “lower,” “above,” “upper” and the like, may be used herein for ease of description to describe one element or feature's relationship to another element(s) or feature(s) as illustrated in the figures. The spatial relative terms are intended to encompass different orientations of the device in use or operation in addition to the orientation depicted in the figures. The apparatus may be otherwise oriented (rotated 90 degrees or at other orientations) and the spatial relative descriptors used herein may likewise be interpreted accordingly.

In this disclosure, the symbol “>” denotes greater than, the symbol “<” denotes less than, the symbol “≥” denotes greater than or equal to, and the symbol “≤” denotes less than or equal to.

Referring to FIG. 2, the semiconductor package of the present disclosure includes a die 210 disposed on a substrate 220. The die 210 is electrically connected to the substrate 220 through a plurality of metal bumps 230.

More specifically, the die 210 has a top surface 211, a bottom surface 212, and a plurality of side surfaces 213, wherein the bottom surface 212 is an active surface having a circuit layer 216 thereon. The top surface 211 and the bottom surface 212 are located on different planes. The bottom surface 212 is perpendicularly connected to the side surfaces 213. The circuit layer 216 of the die 210 is electrically connected to the substrate 220 through the metal bumps 230.

In addition, the die 210 further has a platform 250, which is disposed around the top surface 211. The platform 250 is substantially flat and parallel to the top surface 211 and the bottom surface 212. The distance from the platform 250 to the bottom surface 212 is less than that from the top surface 211 to the bottom surface 212. It means the platform 250 is lower than the top surface 211. Therefore, a step is formed between the top surface 211 and the platform 250. An outer peripheral edge 253 of the platform 250 is connected to the side surfaces 213. The platform 250 is perpendicularly connected to the side surfaces 213.

A molding layer 240 is formed on the substrate 220. The molding layer 240 is made of a molding material, such as epoxy resin, but is not limited thereto. The molding layer 240 has opposing top surface 241 and bottom surface 242, wherein the bottom surface 242 in in contact with the substrate 220. The molding layer 240 is formed to cover the side surfaces 213 and platform 250 of the die 210, and is not formed on the top surface 211 of the die 210. The molding layer 240 exposes the top surface 211 of the die 210. The top surface 241 of the molding layer 240 is connected to the top surface 211 of the die 210 and is flush with the top surface 211 of the die 210.

The semiconductor package of the present disclosure further includes a heat spreader 260 attached to the top surface 211 of the die 210. The heat spreader 260 may be made of copper or other thermally conductive materials to help dissipate heat from the die 210. In addition, a plurality of solder balls 270 is disposed on the bottom surface of the substrate 220. The solder balls 270 are electrically connected to the substrate 220. The die 210 may be electrically connected to an external circuit through the substrate 220 using the solder balls 270.

According to the semiconductor package of the present disclosure, the distance from the top surface 211 to the platform 250 of the die 210, i.e., the depth of the platform 250 is defined as d. The distance from the top surface 211 to the bottom surface 212 of the die 210, i.e., the thickness of the die 210 is defined as D, where D has the following relationship with d:

$$1 / 2 < d / D < 2 / 3$$

In the semiconductor package of the present disclosure, as the molding layer covers the platform, it hooks onto the die like a hook so that the die is not easily separated from the molding layer.

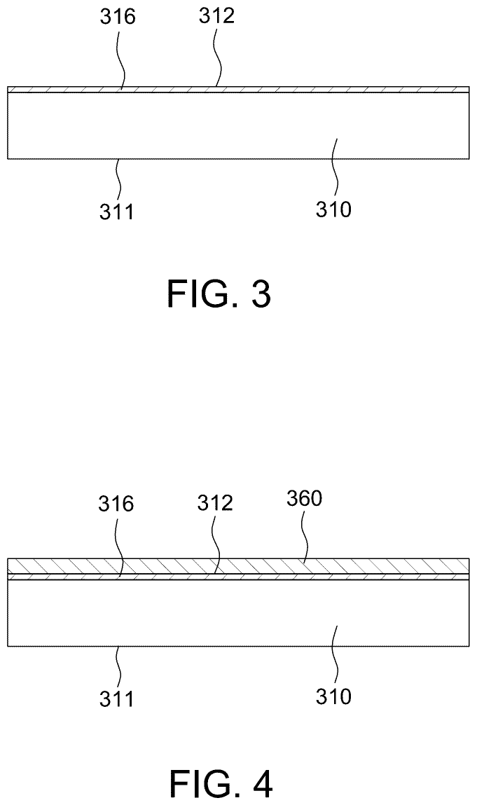

Referring to FIGS. 3 to 8, which illustrate a method of manufacturing the die 210 of FIG. 2. First, as shown in FIG. 3, a wafer 310 having opposing front surface 312 and back surface 311 is provided. The wafer 310 has a circuit layer 316 formed on the front surface 312.

Afterwards, as shown in FIG. 4, a protective film 360 is attached to the front surface 312 of the wafer 310 to protect the circuit layer 316 from damage.

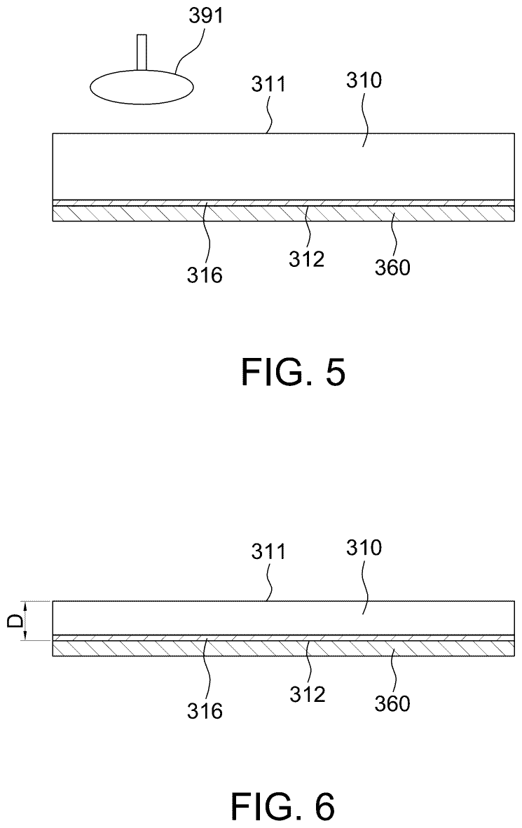

Next, as shown in FIG. 5, the protective film 360 on the wafer 310 is held by a holding surface of a worktable (not shown), and the back surface 311 of the wafer 310 is ground with a grinding bit 391 to thin the wafer 310 to a predetermined thickness. FIG. 6 shows that the wafer 310 has been thinned to the predetermined thickness of D after being ground.

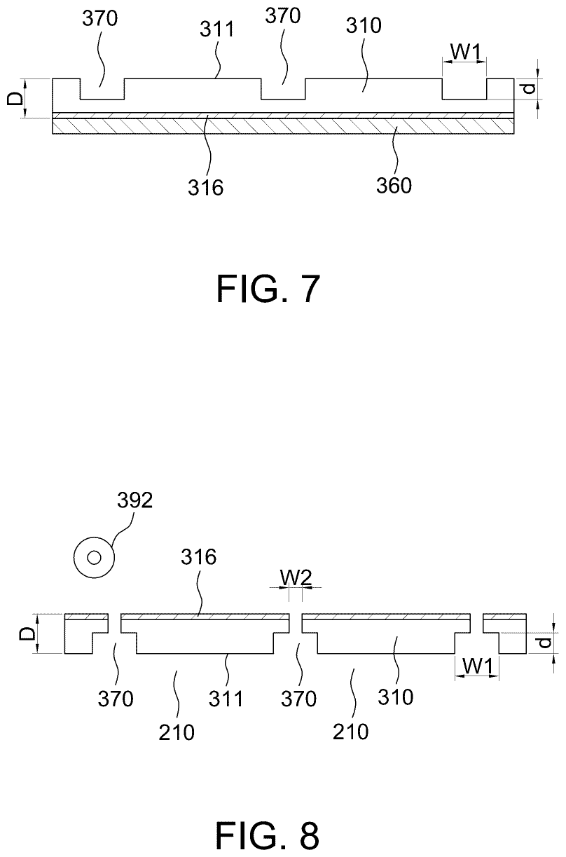

Next, as shown in FIG. 7, a blade or a laser beam is used to form a plurality of grooves 370 on the back surface 311 of the wafer 310, where the grooves 370 have a depth of d and a width of W1.

In one embodiment, the thickness D of the wafer 310 and the depth d of the grooves 370 have the following relationship:

$$1 / 2 < d / D < 2 / 3$$

In another embodiment of the present disclosure, the grooves 370 may be formed on the back surface 311 of the wafer 310 before the wafer 310 is thinned.

Next, as shown in FIG. 8, the protective film 360 is removed from the front surface 312 of the wafer 310. Afterwards, a dicing blade 392 with a thickness of W2 is used to dice the wafer 310 from the front surface 312 to the grooves 370. The wafer 310 is then divided into a plurality of dies 210 shown in FIG. 2.

In one embodiment, the width W1 of the grooves 370 and the thickness W2 of the dicing blade 392 have the following relationship:

$$1 / 2 < W 2 / W 1 < 1$$

The die 210 obtained above may be disposed on a substrate 220 through flip chip technology, and be electrically connected to the substrate 220 by a plurality of metal bumps 230. Thereafter, a molding layer 240 is formed on the substrate 220 and a plurality of solder balls 270 is formed on the bottom surface of the substrate 220. A heat spreader 260 is attached to the top surface 211 of the die 210. Finally, a semiconductor package as shown in FIG. 2 is obtained accordingly.

Although the preferred embodiments of the disclosure have been disclosed for illustrative purposes, those skilled in the art will appreciate that various modifications, additions and substitutions are possible, without departing from the scope and spirit of the disclosure as disclosed in the accompanying claims.

1. A die, comprising:
a top surface;
a plurality of side surfaces;
a bottom surface connected to the side surfaces;
a circuit layer formed on the bottom surface; and
a platform disposed around the top surface, the platform being parallel to the top surface and the bottom surface, a distance from the platform to the bottom surface being less than a distance from the top surface to the bottom surface, the platform being perpendicularly connected to the side surfaces.

2. The die as claimed in claim 1, wherein the distance from the top surface to the platform is defined as d and the distance from the top surface to the bottom surface is defined as D, where D and d have the following relationship:
$$1 / 2 < d / D < 2 / 3.$$

3. A semiconductor package, comprising:
a substrate;
the die of claim 1 disposed on the substrate;
a plurality of metal bumps disposed between the substrate and the bottom surface of the die, the metal bumps being electrically connected to the circuit layer of the die; and
a molding layer formed on the substrate to cover the side surfaces and the platform of the die, wherein the molding layer exposes the top surface of the die.

4. The semiconductor package as claimed in claim 3, wherein a top surface of the molding layer is flush with the top surface of the die.

5. The semiconductor package as claimed in claim 4, further comprising:
a heat spreader attached to the top surface of the die.

6. A method of manufacturing a die, comprising:
providing a wafer having a front surface and a back surface opposing to the front surface, wherein a circuit layer is formed on the front surface;
grinding the back surface of the wafer with a grinding bit to thin the wafer to a predetermined thickness;
forming a plurality of grooves on the back surface of the wafer; and
dicing the wafer from the front surface to the grooves with a dicing blade.

7. The method as claimed in claim 6, wherein the thinned wafer has a thickness of D and the grooves have a depth of d, where D and d have the following relationship:
$$1 / 2 < d / D < 2 / 3.$$

8. The method as claimed in claim 6, wherein the grooves have a width of W1 and the dicing blade has a thickness of W2, where W1 and W2 have the following relationship:
$$1 / 2 < W 2 / W 1 < 1.$$

9. The method as claimed in claim 6, wherein the wafer is thinned after the grooves are formed on the back surface of the wafer.

10. The method as claimed in claim 6, further comprising:
before grinding the wafer, attaching a protective film to the front surface of the wafer; and
after grinding the wafer, removing the protective film from the front surface of the wafer.
